(19) United States
(12) Patent Application Publication
(10) Pub. No.: US 2025/0271999 A1
(43) Pub. Date: Aug. 28, 2025

(54) MEMORY DEVICE, MEMORY SYSTEM, AND METHOD OF OPERATING THE SAME

(71) Applicant: YANGTZE MEMORY TECHNOLOGIES CO., LTD., Wuhan (CN)

(72) Inventors: Teng ZHOU, Wuhan (CN); Hua TAN, Wuhan (CN)

(21) Appl. No.: 18/615,697

(22) Filed: Mar. 25, 2024

Related U.S. Application Data
(63) Continuation of application No. PCT/CN2024/078070, filed on Feb. 22, 2024.

(51) Int. Cl. G06F 3/06

(52) U.S. Cl. CPC G06F 3/0619; G06F 3/0659; G06F 3/0679

(57) ABSTRACT

A method of operating a memory system includes performing a first read operation with a first read voltage of a first single read level, determining an actual pattern of bit count under the first read voltage of the first single read level, and in response to that a difference between an expected pattern of bit count and the actual pattern of bit count under the first read voltage of the first single read level is equal to or lower than a first threshold, determining that the first read voltage is a first optimal read voltage. The first single read level of a first page is under a multi-level architecture.

### CROSS-REFERENCE TO RELATED APPLICATIONS

This application is a continuation of International Application No. PCT/CN2024/078070, filed on Feb. 22, 2024, entitled “MEMORY DEVICE, MEMORY SYSTEM, AND METHOD OF OPERATING THE SAME,” which is incorporated herein by reference in its entirety.

### BACKGROUND

The present disclosure relates to a memory device, a memory system, and a method of operating the same.

In a non-volatile memory device, as multi-bit per memory cell storage architecture emerges and becomes more popular in the industry, read margins become narrower, and thus, memory devices are more vulnerable to noises, program/read disturbances, coupling issues, charge loss, etc. Accordingly, more read errors occur during the read operation. Therefore, several solutions are introduced to minimize the raw bit-error rate (RBER) of memory cells.

### SUMMARY

In one aspect, a method of operating a memory system includes performing a first read operation with a first read voltage of a first single read level, determining an actual pattern of bit count under the first read voltage of the first single read level, and in response to that a difference between an expected pattern of bit count and the actual pattern of bit count under the first read voltage of the first single read level is equal to or lower than a first threshold, determining that the first read voltage is a first optimal read voltage. The first single read level of a first page is under a multi-level architecture.

In some implementations, in response to that the difference between the expected pattern of bit count and the actual pattern of bit count under the first read voltage of the first single read level is higher than the first threshold, determining that the first read voltage is not the first optimal read voltage.

In some implementations, the expected pattern includes an expected ratio of bit count, and the actual pattern comprises an actual ratio of bit count.

In some implementations, in response to determining that the first read voltage is not the first optimal read voltage, the method further includes performing a first shift-read operation with a first shift-read voltage of the first single read level. The first shift-read voltage is determined based on a comparison between the expected ratio of bit count and the actual ratio of bit count under the first read voltage of the first single read level.

In some implementations, the first shift-read voltage is determined based on a comparison between an expected ratio of bit count and an actual ratio of bit count under the first read voltage of the first single read level further includes, in response to that the expected ratio of bit count is higher than the actual ratio of bit count, the first shift-read voltage is determined to be higher than the first read voltage, and in response to that the expected ratio of bit count is lower than the actual ratio of bit count, the first shift-read voltage is determined to be lower than the first read voltage.

In some implementations, in response to that the expected ratio of bit count is higher than the actual ratio of bit count, the first shift-read voltage is determined to be the first read voltage plus a first offset voltage, and in response to that the expected ratio of bit count is lower than the actual ratio of bit count, the first shift-read voltage is determined to be the first read voltage minus a first offset voltage.

In some implementations, after performing the first read operation with the first read voltage of the first single read level, the method further includes counting bit count under the first read voltage of the first single read level.

In some implementations, counting bit count under the first read voltage of the first single read level further includes counting bit count of target memory cells, all the memory cells in a target page, memory cells in one or more pages including the target page, or all the memory cells in all the pages.

In some implementations, determining actual pattern of bit count under the first read voltage of the first single read level further includes calculating a ratio of a first actual bit count to a second actual bit count to determine the actual ratio of bit count. Determining expected ratio of bit count of each read levels for the first page includes calculating a ratio of a first expected bit count to a second expected bit count to determine the expected ratio of bit count.

In some implementations, in response to determining that the first read voltage is the first optimal read voltage, the method further includes determining a second voltage of a second single read level.

In some implementations, in response to determining all the optimal read voltages, the method further includes performing a normal-read operation based on all the optimal read voltages. The normal-read operation is not a first read operation.

In some implementations, the method further includes performing a first pre-read operation with a first pre-read voltage, based on a first bit count in the first pre-read operation and a first relationship between bit count and read offset in the first single read level, determining a first read offset, and determining the first read voltage based on the first pre-read voltage and the first read offset.

In some implementations, the method further includes determining each relationship for each read level using the first relationship of the first single read level.

In some implementations, determining each relationship for each read level further includes determining each relationship between a first voltage offset of the first single read level and each of other voltage offsets of other read levels.

In some implementations, after determining that the first read voltage is a first optimal read voltage, and in response to that a number of an error correction code (ECC) error is greater than an ECC threshold, the method further includes performing a second read operation with the first optimal read voltage of the first single read level, performing a first shift-read operation with the first optimal read voltage plus a first offset voltage, performing a second shift-read operation with the first optimal read voltage minus the first offset voltage, and in response to that a difference between first bit flip information of the first shift-read operation and second bit flip information of the second shift-read operation is equal to or lower than a second threshold, determining that the first optimal read voltage is a second optimal read voltage.

In some implementations, the method further includes, in response to that the difference between the first bit flip information of the first shift-read operation and the second bit flip information of the second shift-read operation is higher than the second threshold, determining that the first optimal read voltage is not the second optimal read voltage, and performing a third read operation with a third read voltage. The third read voltage is determined based on the difference between the first bit flip information of the first shift-read operation and the second bit flip information of the second shift-read operation.

In another aspect, a method of operating a memory system includes determining all optimal read voltages and performing a normal-read operation based on all the optimal read voltages to read out data. Determining all optimal read voltages includes performing a first read operation with a first read voltage of a first single read level, determining an actual pattern of bit count under the first read voltage of the first single read level, and in response to that a difference between an expected pattern of bit count and the actual pattern of bit count under the first read voltage of the first single read level is equal to or lower than a first threshold, determining that the first read voltage is a first optimal read voltage. The first single read level is in a first page under a multi-cell architecture.

In some implementations, the method further includes correcting any errors in the data using an error correction code (ECC).

In still another aspect, a memory device includes a memory cell array and a peripheral circuit coupled to the memory cell array. The memory cell array includes memory cells. The peripheral circuit is configured to: apply a first read voltage of a first single read level to target memory cells in a first read operation, and apply a first shift-read voltage of the first single read level to the target memory cells in a first shift-read operation. The first shift-read voltage is determined based on bit count under the first read voltage of the first single read level.

In some implementations, the peripheral circuit is further configured to: store the bit count in a page buffer of the peripheral circuit or the memory cell array.

In yet still another aspect, a memory system includes a memory device, and a memory controller coupled to the memory device. The memory device includes a memory cell array including memory cells, and a peripheral circuit coupled to the memory cell array. The memory controller is configured to: perform a first read operation with a first read voltage of a first single read level, determine an actual pattern of bit count under the first read voltage of the first single read level, and in response to that a difference between an expected pattern of bit count and the actual pattern of bit count under the first read voltage of the first single read level is equal to or lower than a first threshold, determine that the first read voltage is a first optimal read voltage. The first single read level of a first page is under a multi-level architecture.

In yet still another aspect, a non-transitory computer-readable medium storing instructions that, when executed by a processor, cause the processor to perform a method including performing a first read operation with a first read voltage of a first single read level, determining an actual pattern of bit count under the first read voltage of the first single read level, and in response to that a difference between an expected pattern of bit count and the actual pattern of bit count under the first read voltage of the first single read level is equal to or lower than a first threshold, determining that the first read voltage is a first optimal read voltage. The first single read level of a first page is under a multi-level architecture.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a schematic circuit diagram of an example memory device including peripheral circuits, according to some implementations of the present disclosure.

FIG. 2 illustrates a block diagram of an example memory device including a memory cell array and peripheral circuits, according to some implementations of the present disclosure.

FIG. 3 illustrates a block diagram of an example memory system including a host, a memory controller, and a memory device, according to some implementations of the present disclosure.

FIG. 4 illustrates a read recovery flowchart during an operation of an example memory system, according to some implementations of the present disclosure.

FIG. 5A illustrates a voltage distribution and corresponding read levels showing an example method for determining an optimal read voltage, according to some implementations of the present disclosure.

FIG. 5B illustrates a bit count chart with corresponding read levels showing an example method for determining an optimal read voltage, according to some implementations of the present disclosure.

FIG. 6A illustrates a voltage distribution showing an example method for determining an optimal read voltage, according to some implementations of the present disclosure.

FIG. 6B illustrates a voltage distribution during a read operation showing an example method for determining an optimal read voltage, according to some implementations of the present disclosure.

FIG. 6C illustrates a voltage distribution showing an example method for determining an optimal read voltage, according to some implementations of the present disclosure.

FIG. 6D illustrates a table including bit count information in each read level showing an example method for determining an optimal read voltage, according to some implementations of the present disclosure.

FIG. 6E illustrates a table including bit count information in each read level showing an example method for determining an optimal read voltage, according to some implementations of the present disclosure.

FIG. 7A illustrates a flowchart for determining an optimal read voltage, according to some implementations of the present disclosure.

FIG. 7B illustrates a flowchart for determining an optimal read voltage, according to some implementations of the present disclosure.

FIG. 8A illustrates a voltage distribution and corresponding relationship between read offset and bit count number during a read operation, according to some implementations of the present disclosure.

FIG. 8B illustrates a relationship in different optimal read voltage levels, according to some implementations of the present disclosure.

FIG. 9A illustrates a flowchart for determining an optimal read voltage, according to some implementations of the present disclosure.

FIG. 9B illustrates a flowchart for determining an optimal read voltage, according to some implementations of the present disclosure.

FIG. 9C illustrates a flowchart for determining an optimal read voltage, according to some implementations of the present disclosure.

FIG. 10 illustrates a block diagram of an example system having a memory device, according to some implementations of the present disclosure.

FIG. 11A illustrates a diagram of an example memory card having a memory device, according to some implementations of the present disclosure.

FIG. 11B illustrates a diagram of an example solid-state drive (SSD) having a memory device, according to some implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

In a non-volatile memory device, multi-bit per memory cell storage architecture emerges and becomes popular in the industry. Read margins become narrower, and thus, the memory devices are more vulnerable to various types of noises, program/read disturbances, coupling issues, charge loss, etc. For example, multi-level cell (MLC) technology significantly reduces read margins between different threshold voltage (Vth) levels used to store multiple bits in a single memory cell. However, Vth levels of the memory cells may shift beyond the read reference voltages (Vref), i.e., the voltage used to distinguish between cell Vth levels, which leads to more read errors.

One of the approaches is to apply a read retry operation. Read retry operation can be used to determine the optimal read voltages of the memory device. However, a large number of read retry operations may lead to significant performance degradation due to the read latency by introducing multiple read retry steps that read the target page again with adjusted read reference voltages (Vref). Another approach is to apply error-correcting codes (ECC) that may detect and correct raw bit errors. However, ECC can merely detect and correct limited errors. Accordingly, more solutions should be applied in combination with these approaches, thereby reducing the read error rate while maintaining the performance of the memory system.

To address one or more of the aforementioned issues, the present disclosure introduces solutions in which several methods are used to determine optimal read voltages for each read level. In particular, the present disclosure introduces solutions in which a single level read can be used to determine the optimal read voltages such that the time for calculation is reduced and the overall performance is improved. In addition, the present disclosure also provides solutions in which multiple methods for data recovery to correct data and reduce RBER are implemented. It is noted that a single level read is a read operation that read out at least a bit of data stored in a memory cell as one order bit “0” or “1” using a single reference voltage level (e.g., a single read reference voltage level). The data stored in the memory cell may include multiple bits (e.g., 110, 001, or 011). The single reference voltage level may be, for example, a first single read level (RV1) to distinguish adjacent program states (e.g., L0 and L1) from each other. For example, the first single read level (RV1) voltage (V_{RV1}) may be applied to a word line connected to a target memory cell and a pass voltage is applied to the other word lines. And then, at least a bit of data stored in the target memory cell can be determined as “0” or “1” depending on whether current is detected under the first single read level voltage V_{RV1} in a bit line connected to the target memory cell. It is noted that, in some implementations, the bit count disclosed herein is the number of either bit=1 or bit=0, under the single level read operation.

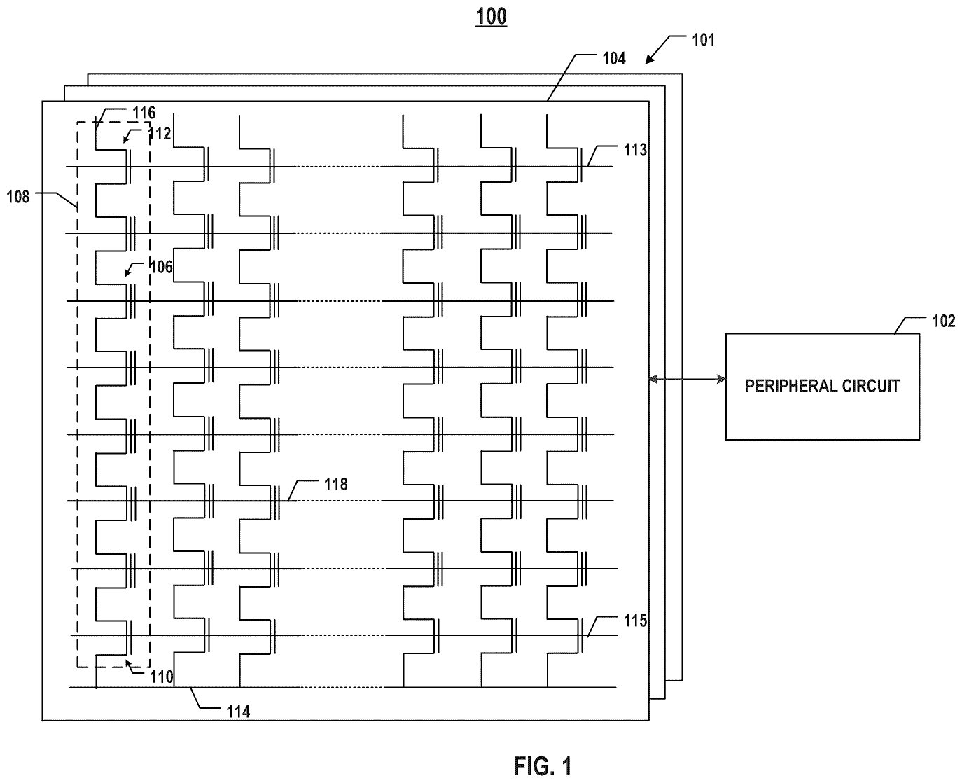

FIG. 1 illustrates a schematic circuit diagram of a memory device 100 including peripheral circuits, according to some aspects of the present disclosure. Memory device 100 can include a memory cell array 101 and peripheral circuits 102 coupled to memory cell array 101. In some implementations, memory cell array 101 can be a NAND Flash memory cell array in which memory cells 106 are provided in the form of an array of three-dimensional (3D) NAND memory strings 108 each extending vertically above a substrate (not shown). In some implementations, each 3D NAND memory string 108 includes a plurality of memory cells 106 coupled in series and stacked vertically. Each memory cell 106 can hold a continuous, analog value, such as an electrical voltage or charge, that depends on the number of electrons trapped within a region of memory cell 106. Each memory cell 106 can be either a floating gate type of memory cell including a floating-gate transistor or a charge trap type of memory cell including a charge-trap transistor. Each array of 3D NAND memory strings 108 can include one or more 3D memory devices.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in four or more memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state. It is noted that a multi-level architecture in the present disclosure includes an MLC architecture, a TLC architecture, a QLC architecture, or the like, or a combination thereof.

As shown in FIG. 1, each 3D NAND memory string 108 can include a source select transistor 110 at its source end and a drain select transistor 112 at its drain end. Source select transistor 110 and drain select transistor 112 can be configured to activate selected 3D NAND memory strings 108 (columns of the array) during read and program operations. In some implementations, the sources of source select transistors 110 of 3D NAND memory strings 108 in the same block 104 are coupled through a same source line (SL) 114, e.g., a common SL, for example, to the ground. Drain select transistor 112 of each 3D NAND memory string 108 is coupled to a respective bit line 116 from which data can be read or programmed via an output bus (not shown), according to some implementations. In some implementations, each 3D NAND memory string 108 is configured to be selected or unselected by applying a select signal (e.g., a select voltage above the threshold voltage of drain select transistor 112) or a deselect signal (e.g., a deselect voltage such as 0 V) to respective drain select transistor 112 through one or more drain select lines 113 and/or by applying a select voltage (e.g., above the threshold voltage of source select transistor 110) or a deselect voltage (e.g., 0 V) to respective source select transistor 110 through one or more source select lines 115.

As shown in FIG. 1, 3D NAND memory strings 108 can be organized into multiple blocks 104, each of which can have a common source line 114. In some implementations, each block 104 is the basic data unit for erase operations, i.e., all memory cells 106 on the same block 104 are erased at the same time. Memory cells 106 can be coupled through word lines 118 that select which row of memory cells 106 is affected by read and program operations. In some implementations, each word line 118 is coupled to a row of memory cells 106, which is the basic data unit for program and read operations. Each word line 118 can be coupled to a plurality of control gates (gate electrodes) at each memory cell 106 in a respective row and a gate line coupling the control gates.

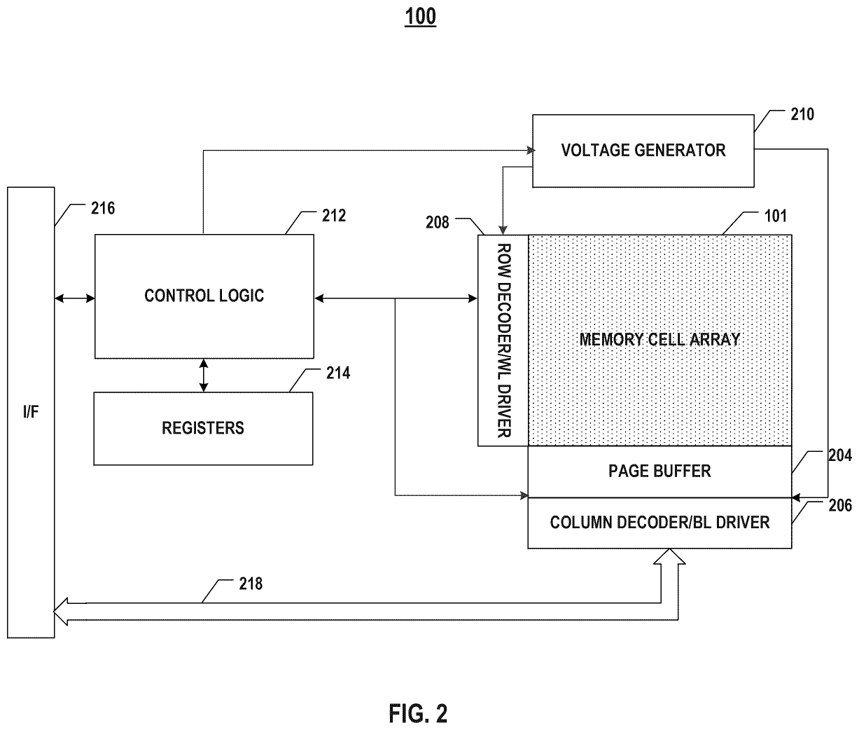

Peripheral circuits 102 can be coupled to memory cell array 101 through bit lines 116, word lines 118, source lines 114, source select lines 115, and drain select lines 113. As described above, peripheral circuits 102 can include any suitable circuits for facilitating the operations of memory cell array 101 by applying and sensing voltage signals and/or current signals through bit lines 116 to and from each target memory cell 106 through word lines 118, source lines 114, source select lines 115, and drain select lines 113. Peripheral circuits 102 can include various types of peripheral circuits formed using complementary metal-oxide semiconductor (CMOS) technologies. For example, FIG. 2 illustrates example peripheral circuits 102 including a page buffer 204, a column decoder/bit line driver 206, a row decoder/word line driver 208, a voltage generator 210, control logic 212, registers 214, an interface (I/F) 216, and a data bus 218. It is understood that in some examples, additional peripheral circuits 102 may be included as well.

Page buffer 204 can be configured to buffer data read from or programmed to memory cell array 101 according to the control signals of control logic 212. In one example, page buffer 204 may store one or more pages of program data (write data) to be programmed into one or more rows of memory cell array 101. In another example, page buffer 204 also performs program verify operations to ensure that the data has been properly programmed into memory cells 106 coupled to selected word lines 118. In yet another example, page buffer 204 may also store bit information, bit flip information, bit count, bit count information, offset information, intermediate calculation data, data tables, or other information that is used to implement the methods in the present disclosure.

Row decoder/word line driver 208 can be configured to be controlled by control logic 212 and select or unselect a block 104 of memory cell array 101 and select or unselect a word line 118 of selected block 104. Row decoder/word line driver 208 can be further configured to drive memory cell array 101. For example, row decoder/word line driver 208 may drive memory cells 106 coupled to the selected word line 118 using a word line voltage generated from voltage generator 210. In some implementations, row decoder/word line driver 208 can include a decoder and string drivers (driving transistors) coupled to local word lines and word lines 118.

Voltage generator 210 can be configured to be controlled by control logic 212 and generate the word line voltages (e.g., read voltage, program voltage, pass voltage, local voltage, verification voltage, etc.) to be supplied to memory cell array 101. In some implementations, voltage generator 210 is part of a voltage source that provides voltages at various levels of different peripheral circuits 102 as described below in detail. Consistent with the scope of the present disclosure, in some implementations, the voltages provided by voltage generator 210, for example, to row decoder/word line driver 208 and page buffer 204 are above certain levels that are sufficient to perform the memory operations. For example, the voltages provided to page buffer 204 may be between 2 V and 3.3 V, such as 3.3 V, and the voltages provided to row decoder/word line driver 208 may be greater than 3.3 V, such as between 3.3 V and 30 V.

Column decoder/bit line driver 206 can be configured to be controlled by control logic 212 and select one or more 3D NAND memory strings 108 by applying bit line voltages generated from voltage generator 210. For example, column decoder/bit line driver 206 may apply column signals for selecting a set of N bits of data from page buffer 204 to be output in a read operation.

Control logic 212 can be coupled to each peripheral circuit 102 and configured to control operations of peripheral circuits 102. Registers 214 can be coupled to control logic 212 and include status registers, command registers, and address registers for storing status information, command operation codes (OP codes), and command addresses for controlling the operations of each peripheral circuit 102. Control logic 212 is configured to control the operations in the implementations of the present disclosure.

Interface 216 can be coupled to control logic 212 and configured to interface memory cell array 101 with a memory controller (not shown). In some implementations, interface 216 acts as a control buffer to buffer and relay control commands received from the memory controller and/or a host (not shown) to control logic 212 and status information received from control logic 212 to the memory controller and/or the host. Interface 216 can also be coupled to page buffer 204 and column decoder/bit line driver 206 via data bus 218 and act as an Input/Output (I/O) interface and a data buffer to buffer and relay the program data received from the memory controller and/or the host to page buffer 204 and the read data from page buffer 204 to the memory controller and/or the host. In some implementations, interface 216 and data bus 218 are part of an I/O circuit of peripheral circuits 102.

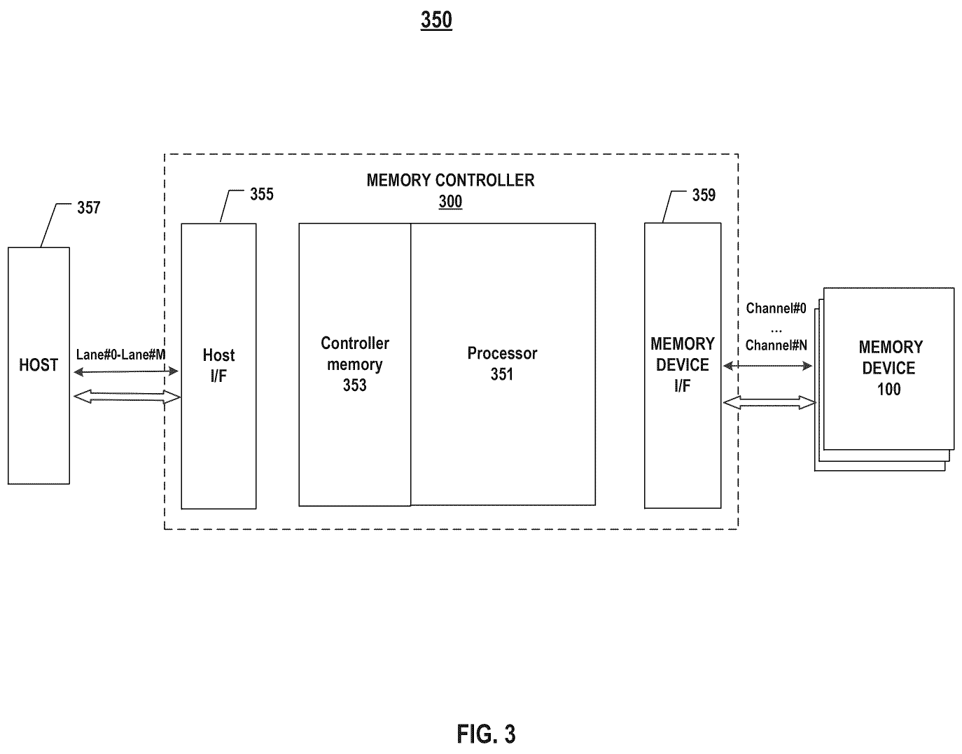

FIG. 3 illustrates an example memory system 350 including a host 357, a memory controller 300, and a memory device 100, according to some implementations of the present disclosure. Memory controller 300 includes a microprocessor 351, controller/host interface (I/F) 355 coupled between microprocessor 351 and host 357, and controller/memory device interface 359 coupled between microprocessor 351 and memory device 100. Controller/host interface 355 is configured to implement a standard communication protocol including an embedded MultiMedia Card (eMMC), Universal Serial Bus (USB), Universal Flash Storage (UFS), Parallel Advanced Technology Attachment (Parallel ATA or PATA), Serial Advanced Technology Attachment (SATA), etc., for communicating with host 357. Controller/memory device interface 359 is configured to transfer a command into corresponding control signal that controls memory device 100.

Memory controller 300 may manage data stored in memory device 100 and communicate with host 357. Memory controller 300 may be configured to control operations of memory device 100, such as read, erase, program operations, data recovery operations, or other operations according to some implementations of the present disclosure. Memory controller 300 may be configured to control the operations by sending a command (e.g., a read command) or a command with data addresses. In some implementations, memory controller 300 may also include a controller memory 353 (such as a volatile cache memory and/or a non-volatile memory) storing data tables, intermediate calculation information, offset information, verify information, fail bit count information, bit information, bit flip information, bit count, bit count information, or other information in the implementations of the present disclosure. Memory controller 300 may also be configured to manage various functions with respect to data stored or to be stored in memory device 100, including but not limited to bad block management, garbage collection, logical to physical address transfer, and wear leveling. In some implementations, memory controller 300 is also configured to process error correction codes (ECC) with respect to data read from or written to memory device 100. In some implementations, memory controller 300 is also configured to perform or instruct to perform operations including the optimal read voltage determining operation, read retry operation, or other operations in the implementations of the present disclosure. Memory controller 300 may also perform any other suitable function, such as formatting memory device 100. Memory controller 300 may communicate with external devices (e.g., host 357) according to a particular communication protocol. Host 357 may be a processor (e.g., a central processing unit (CPU)) or a system on a chip (SoC) (e.g., an application processor (AP)) of the electronic device. Host 357 may be configured to send data to or receive data from memory device 100 via memory controller 300.

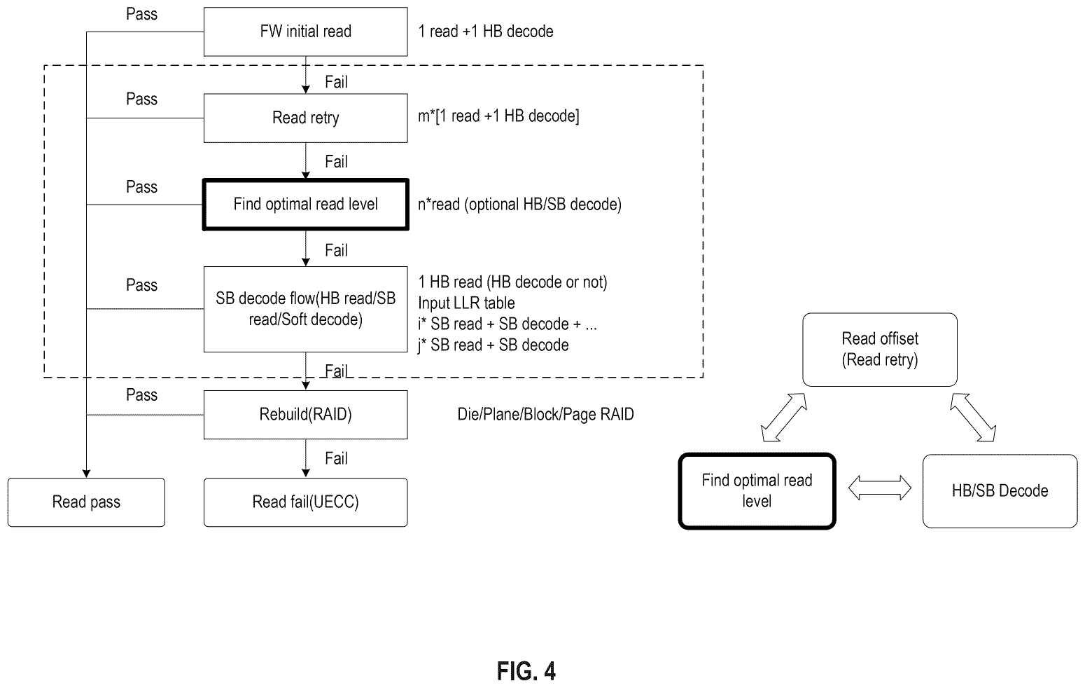

FIG. 4 illustrates a read recovery flowchart during an operation of an example memory system, according to some implementations of the present disclosure. First, the firmware may instruct memory controller 300 to read with an initial threshold voltage and attempts a hard decoding of read information. If the initial threshold voltage is chosen well such that the initial read passes, the hard decoding will succeed, and the decoded read information is sent to host 357. Otherwise, if the hard decoding fails, the initial read also fails, the firmware may instruct memory controller 300 to perform a read retry operation, an optimal read voltage determining operation, or a combination thereof.

In some implementations, the optimal read voltage determining operation may be performed when the initial read fails. Afterwards, the optimal read voltage determining operation may use a default read voltage of the initial read operation as a first read voltage (i.e., as an initial read voltage of the optimal read voltage determining operation) to start the implementations of the optimal read voltage determining operation. It is noted that the first read voltage in the first read operation in present disclosure may be a single read level voltage in a single read level operation.

In some implementations, the optimal read voltage determining operation may be performed within the read retry operation. For example, during the read retry operation, a read offset voltage may be obtained by checking a read retry table (RRT). The RRT may include a plurality of offset voltage values or include corresponding values that can be calculated to obtain offset voltage values. The offset voltage obtained from the RRT during the read retry operation may be used directly or may be calculated to determine a read retry voltage.

In some implementations, the read retry voltage can be used directly as the first read voltage of the optimal read voltage determining operation to start the implementations of the optimal read voltage determining operation.

In some implementations, the read retry voltage can be used to perform a normal read operation. If the normal read operation passes, no optimal read voltage determining operation is needed. Otherwise, if the normal read operation fails, the read retry voltage is used as the first read voltage of the optimal read voltage determining operation to start the implementations of the optimal read voltage determining operation.

In some implementations, the optimal read voltage determining operation may be performed when the read retry operation fails.

As shown in FIG. 4, the read retry operation may include a read operation and a hard decoding operation for each read retry operation. However, the optimal read voltage determining operation may only require multiple read operations with optional hard decoding or soft decoding operations. Accordingly, the optimal read voltage determining operation, in comparison with the read retry operation, reduces the cost and latency and increases the efficiency in obtaining optimal read voltages for each read level.

To further improve the error correction capability, memory controller 300 may check a log-likelihood ratio (LLR) table generated during the characterization of the memory device. The input of LLR provides statistical information of the memory device about the most likely correct values for each data bit. For example, the LLR may provide soft information that determines the probabilities of how likely the received bit (“0” or “1”) is flipped or not. These probabilities are taken from LLR tables that have been generated and stored in lookup tables in memory controller 300. This operation may be implemented before, within, or after the read retry operation or the optimal read voltage determining operation.

In some implementations, an ECC mechanism may also be implemented before, within, or after the read retry operation or the optimal read voltage determining operation.

If all the read retry operations and the optimal read voltage determining operations fail, it is determined that the memory cells may be defected (e.g., stuck cells), and thus it is determined that there is an uncorrectable ECC failure (or UECC). A redundant array of independent disks (RAID) and the corresponding components (i.e., die/plane/block/page) may be rebuilt accordingly. For example, the RAID operation may recover a failed component in a RAID stripe by using the remaining successful components in the RAID stripe.

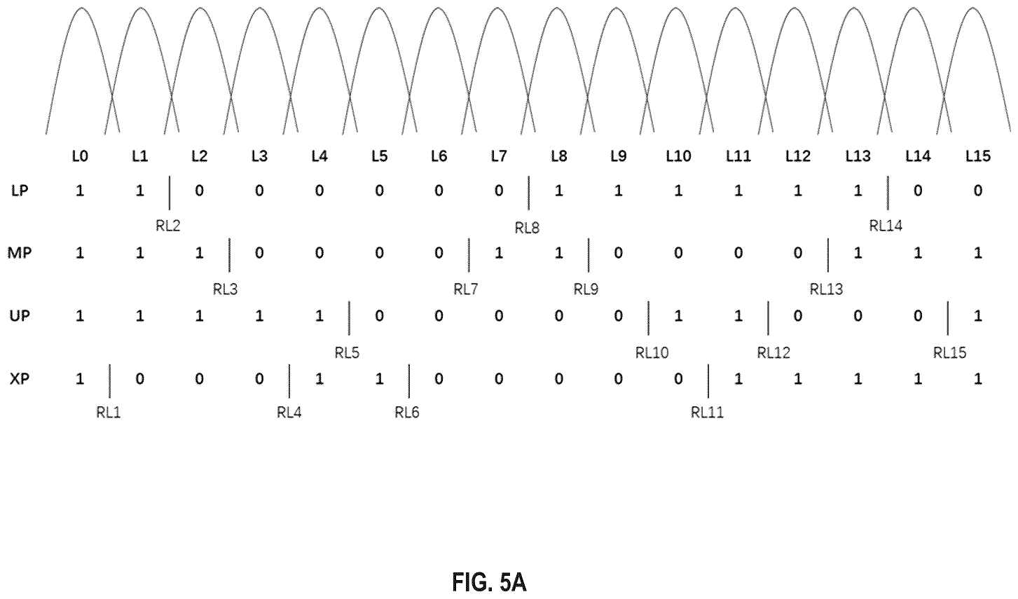

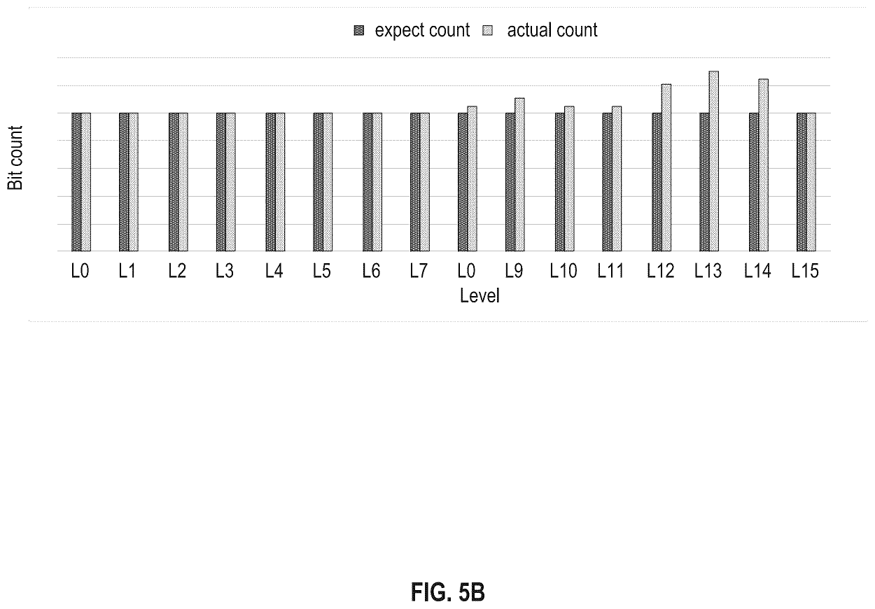

FIGS. 5A-5B illustrate an example method for determining an optimal read voltage, according to some implementations of the present disclosure. As shown in FIG. 5A, this example uses a QLC NAND as an implementation. It is noted that the implementations in the present disclosure may not be limited to QLC architecture. It can also include MLC or TLC architecture. Because the read operation in this implementation is not a single level read operation, a randomness of the bit count of each read levels of all types of pages (i.e., lower page (LP), middle page (MP), upper page (UP), extra page (XP)) is required to find optimal read voltage for one of the read levels. For example, the randomness of the bit count of program state L0 and program state L1 of page XP should be obtained before determining the optimal read voltage for read level 1 (RV1).

In FIG. 5B, in an implementation of optimal read voltage determining operation, the actual bit count (i.e., by reading target memory cells, a portion memory cells in a target page (e.g., memory cells in at least a program state of the target page), all the memory cells in the target page, memory cells in one or more pages including the target page, all the memory cells in all the pages, and counting the bit count thereof) and expected bit count (which is equally distributed among all the read levels of all the pages and can be pre-determined or calculated) are compared and thus a shift of the read voltage in the next iteration of the optimal read voltage determining operation can be determined. It is noted that the actual bit count data collected may include bit count of a target set of memory cells or a target set of pages, and that a target optimal read voltage is the optimal read voltage of the target set of memory cells or pages. As such, the addresses of the read operation to determine the actual bit count can be the addresses of the corresponding target set of memory cells or pages.

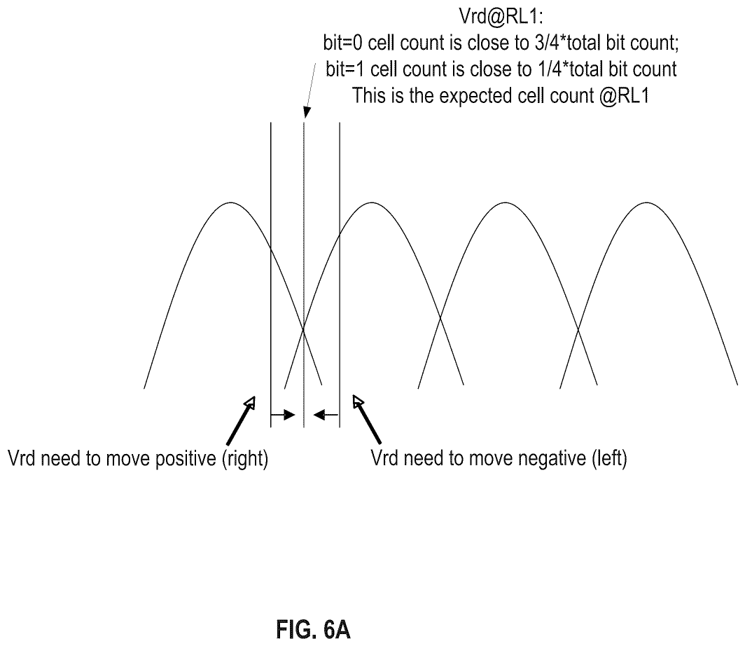

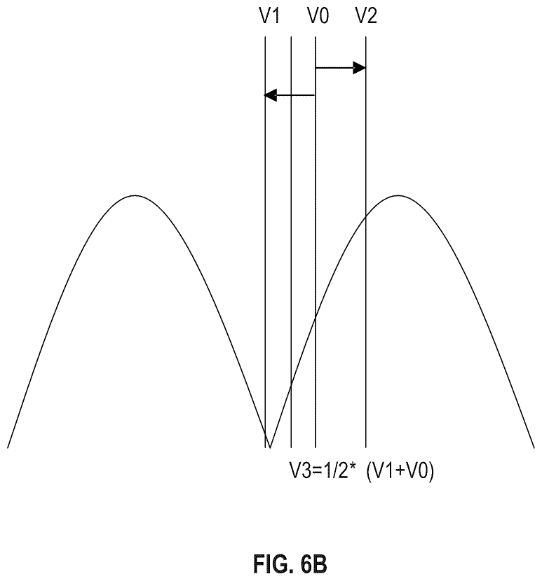

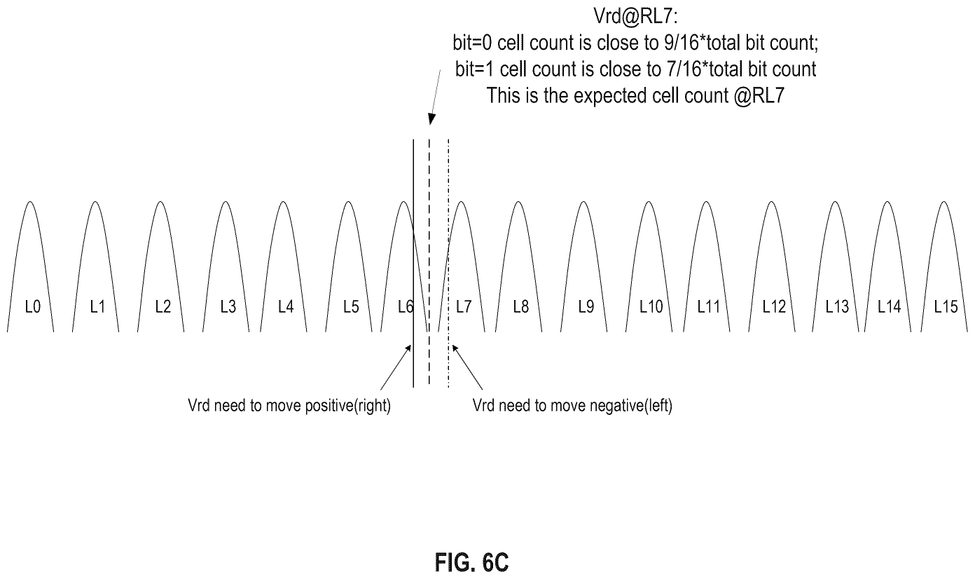

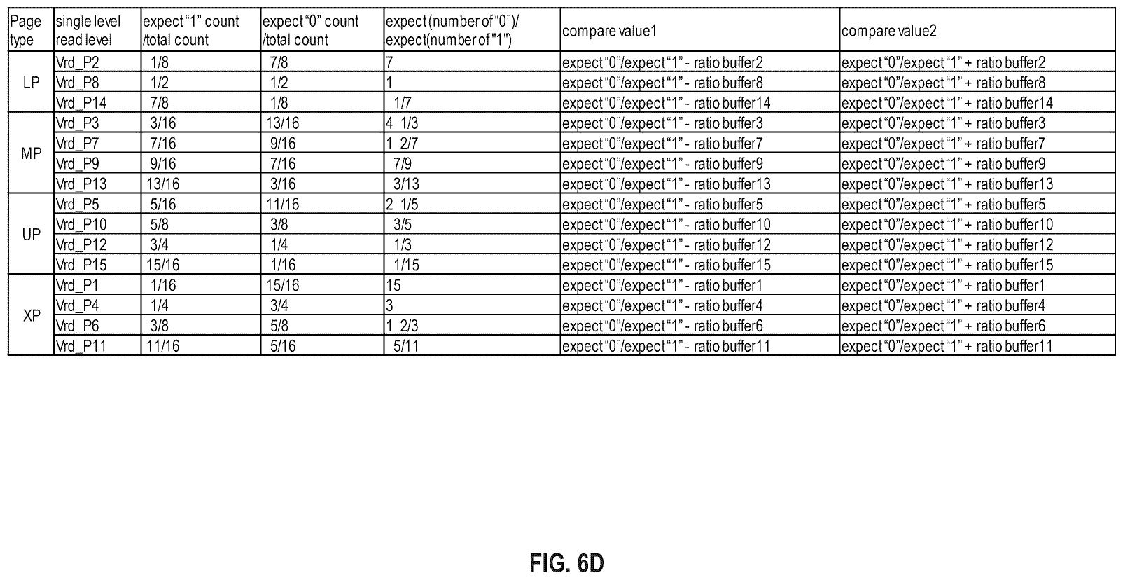

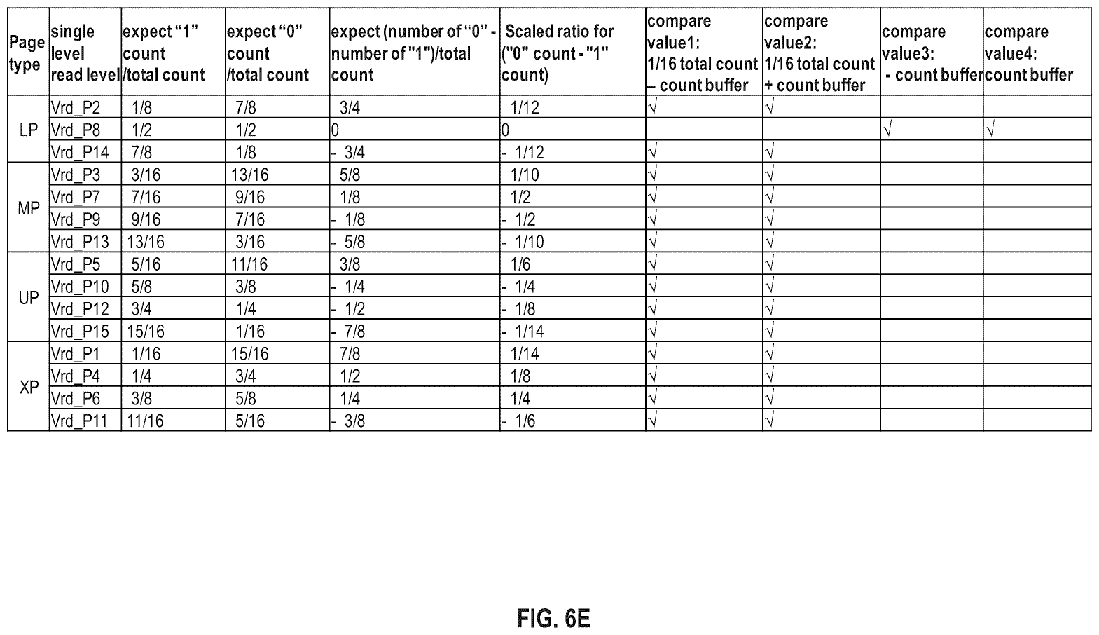

FIG. 6A illustrates a voltage distribution showing an example method for determining an optimal read voltage, according to some implementations of the present disclosure. To find the optimal read voltage, the bit count in a certain Vth is close to a certain amount of total bit count based on the programmed data randomness characteristic in which it can be relied upon such that the expected bit count information and actual bit count information can be used to determine the shift of the read voltage in the next iteration during the optimal read voltage determining operation. For example, as shown in FIG. 6A, during the read voltage Vrd at first read level (RV1), the actual bit count when bit=0 should be close to ¾* total bit count (i.e., the expected bit count), and the actual bit count when bit=1 should be closed to ¼* total bit count. After determining the actual bit count (it is feasible to count the number of either bit=1 or bit=0, both of which can be referred to as the actual bit count herein), by comparing the actual bit count with the expected bit count, the read voltage Vrd can be determined to further move positive (right) or negative (left) in the next iteration during the optimal read voltage determining operation. It is noted that the bit count information includes the number of bit counts or the number of bit counts being processed or biased.

For example, as shown in FIG. 6B, for determining a single-level cell (i.e., two program states) may have bit counts when bit=1 and when bit=0, both of which should be ½ of the total bit count. After applying a first read voltage V0, the actual bit count (when bit=1) is larger than the expected bit count (when bit=1), and the difference between the actual bit count and the expected bit count is more than a threshold, it is determined that the next read voltage in the next iteration should be shifted left to a second read voltage V1.

In the next iteration, applying the second read voltage V1, the actual bit count (when bit=1) is still larger than the expected bit count (when bit=1), and the difference between the actual bit count and the expected bit count is still more than the threshold, it is determined that the next read voltage in the next iteration should be shifted left to a third read voltage V2.

In the next iteration, applying the third read voltage V2, the actual bit count (when bit=1) is smaller than the expected bit count (when bit=1), and the difference between the actual bit count and the expected bit count is more than the threshold, it is determined that the next read voltage in the next iteration should be shifted right to a fourth read voltage V3.

In some implementations, the shift value of the fourth read voltage V3 can be, for example, half of the last shift value when the direction of the shift changes.

In the next iteration, applying the fourth read voltage V3, the actual bit count (when bit=1) is smaller or larger than the expected bit count (when bit=1), but the difference between the actual bit count and the expected bit count is equal to or less than the threshold, it is determined that the fourth read voltage V3 is a first optimal read voltage of a first read level of the current page.

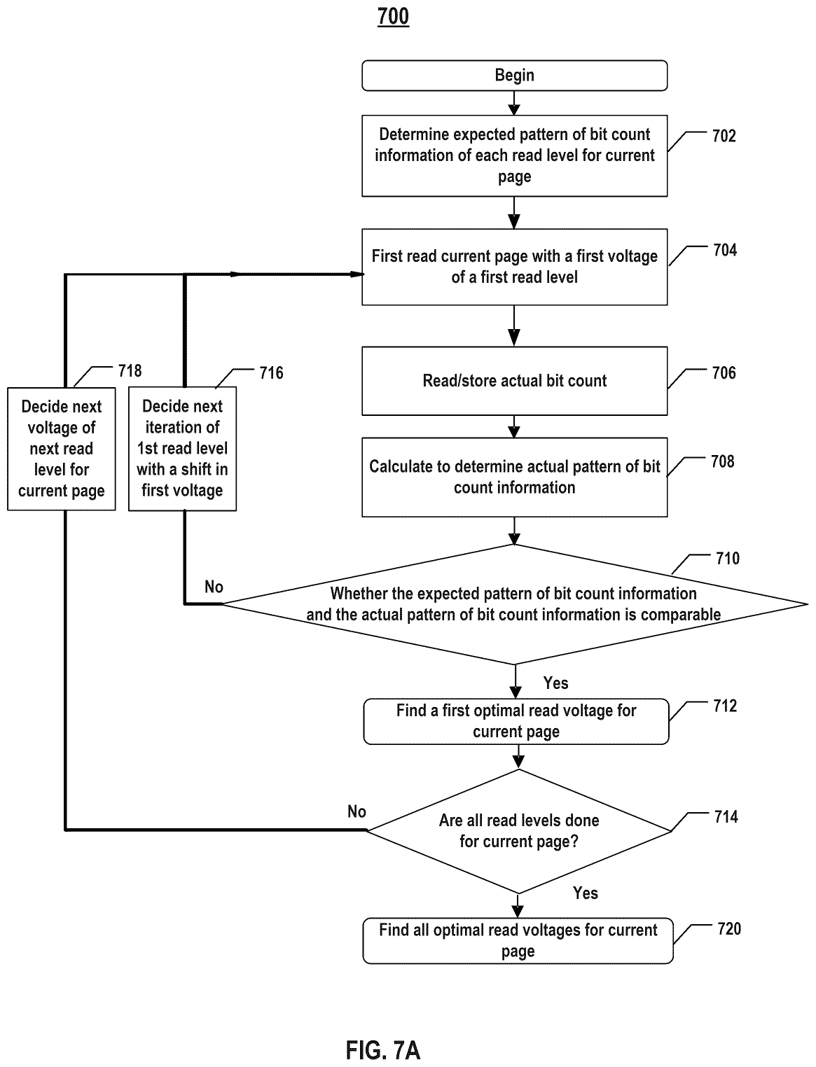

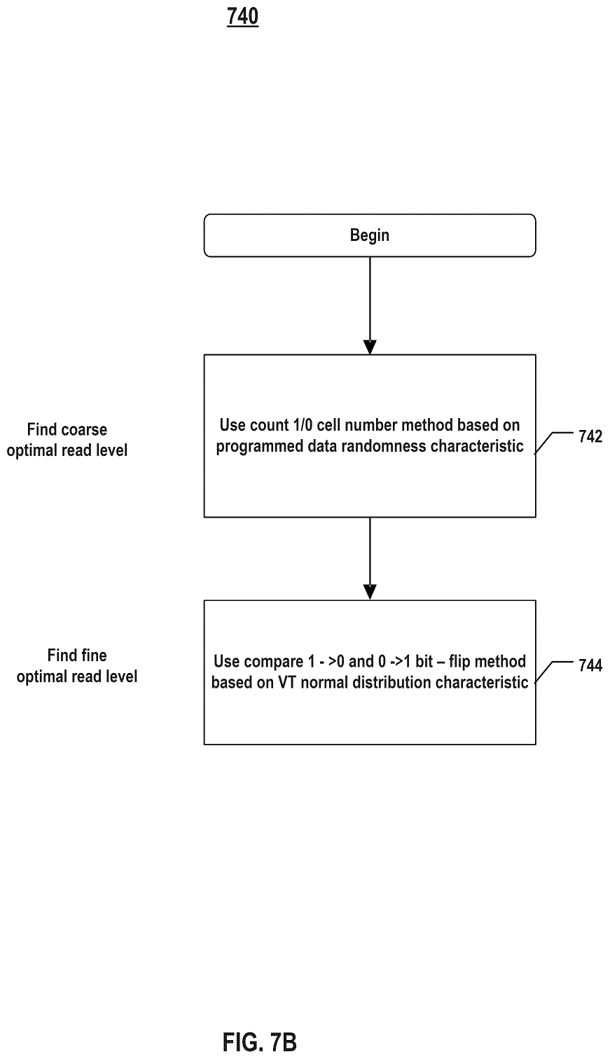

FIG. 7A illustrates a flowchart of method 700 of determining an optimal read voltage in the example of FIGS. 6A-6E, according to some implementations of the present disclosure. It is noted that the implementation can be performed under an MLC, TLC, or QLC architecture.

First, referring to operation 702 in which the expected pattern of bit count information of each read level for the current page is determined. For example, all the expected patterns (e.g., expected ratio of bit count, as shown in FIG. 6D, or scaled ratio of bit count, as shown in FIG. 6E) of bit count information of each read level of each page are determined. It is noted that the pattern of bit count information includes the bit count information, or the bit count information being processed or biased.

In some implementations, a threshold, or a so-called ratio buffer, for example, ratio buffer 1 to ratio buffer 15, is determined according to the randomness characteristic of the programmed data. The randomness characteristic of the programmed data can be determined by big data analysis. That is, the actual bit count information and the expected bit count information may be compared whether they are within the corresponding ratio buffers. If the difference between the actual bit count information and the expected bit count information is equal or less than the corresponding ratio buffers, the current read voltage can be determined to be the optimal read voltage.

Next, referring to operation 704 in which a first read operation is performed on the current page data (i.e., the target page). The read level of the current page, for example, as shown in the implementation in FIG. 6D, a first read operation is applied for a read level Vrd_P3 of page MP, and is read with a first read voltage V0.

Next, referring to operation 706, the actual bit count information is obtained and stored after the first read operation. In some implementations, the actual bit count information can be stored in controller memory 353 of memory controller 300 or page buffer 204 of memory device 100.

The expected pattern of bit count information can be pre-determined according to the randomness characteristic of the programmed data. For example, the expected pattern of bit count information includes the expected bit count when bit=0/the expected bit count when bit=1, as shown in implementations in FIG. 6D. In another example, the expected pattern of bit count information includes (the expected bit count when bit=0−the expected bit count when bit=1)/total bit count. In yet another example, the expected pattern of bit count information includes scaled ratio for (expected bit count when bit=0−the expected bit count when bit=1). For example, for a read operation including a read voltage Vrd_P2 for read level P2 in page LP, the expected bit count when bit=1/total bit count is ⅛ (e.g., 2/16), the expected bit count when bit=0/total bit count is ⅞ (e.g., 14/16), and (the expected bit count when bit=0−the expected bit count when bit=1)/total bit count is ¾ (e.g., 12/16). If using the scaled ratio as a bit count information pattern, the scaled ratio for (expected bit count when bit=0−the expected bit count when bit=1) is 1/12 (e.g., 1/(14-2)).

In some implementations, the expected pattern of bit count information may include compared value 1 (e.g., 1/16 total count—count buffer), compared value 2 (e.g., 1/16 total count+count buffer), compared value 3 (e.g.,—count buffer), and compared value 4 (e.g., count buffer), which can all be pre-determined and can be programmed and stored in memory controller 300 or memory device 100. The count buffer can also be pre-determined according to the randomness characteristic of the programmed data.

Next, referring to operation 708, the actual pattern of bit count information is calculated. For example, the actual pattern of bit count information includes the actual bit count when bit=0/the actual bit count when bit=1, as shown in implementations in FIG. 6D. In another example, the actual pattern of bit count information includes (the actual bit count when bit=0−the actual bit count when bit=1)/total bit count. In yet another example, the actual pattern of bit count information includes scaled ratio for (actual bit count when bit=0−the actual bit count when bit=1).

The actual pattern of bit count information, for example, can be a value of a scaled ratio of (an actual bit count when bit=0−an actual bit count when bit=1). The value can be then compared with the compared value 1, compared value 2, compared value 3, and compared value 4. The actual pattern of bit count information may be compared with the expected pattern of bit count information.

Next, referring to operation 710 in which whether the expected pattern of bit count information and the actual pattern of bit count information are comparable is determined. The following illustrates one of the implementations.

If scaled ratio >0, when scaled ratio*(actual bit count when bit=0−the actual bit count when bit=1)>compared value 2, a first read voltage V0 should shift right, a second read voltage V1 is determined to be the first read voltage V0+a shift value as this iteration; when scaled ratio*(actual bit count when bit=0−the actual bit count when bit=1)<compared value 1, the first read voltage V0 should shift left, the second read voltage V1 is determined to be the first read voltage V0−a shift value as this iteration; when compared value 1<=scaled ratio*(actual bit count when bit=0−the actual bit count when bit=1)<=compared value 2, the first read voltage V0 is determined to be the optimal read voltage of the current level of the current page.

If scaled ratio <0, when scaled ratio*(actual bit count when bit=0−the actual bit count when bit=1)>compared value 2, the first read voltage V0 should shift left, the second read voltage V1 is determined to be the first read voltage V0−a shift value as this iteration; when scaled ratio*(actual bit count when bit=0−the actual bit count when bit=1)<compared value 1, the first read voltage V0 should shift right, the second read voltage V1 is determined to be the first read voltage V0+a shift value as this iteration; when compared value 1<=scaled ratio*(actual bit count when bit=0−the actual bit count when bit=1)<=compared value 2, the first read voltage V0 is determined to be the optimal read voltage of the current level of the current page.

If scaled ratio=0, when (actual bit count when bit=0−the actual bit count when bit=1)>compared value 4, the first read voltage V0 should shift right, the second read voltage V1 is determined to be the first read voltage V0+a shift value as this iteration; when (actual bit count when bit=0−the actual bit count when bit=1)<compared value 3, the first read voltage V0 should shift left, the second read voltage V1 is determined to be the first read voltage V0−a shift value as this iteration; when compared value 3<=actual bit count when bit=0−the actual bit count when bit=1<=compared value 4, the first read voltage V0 is determined to be the optimal read voltage of the current level of the current page.

As such, by applying the above calculations, as shown in operation 716, the second read voltage V1 can be determined, and the next iteration can be repeated.

On the contrary, when the expected pattern of bit count information and the actual pattern of bit count information is not comparable, that is, the difference between the expected pattern of bit count information and the actual pattern of bit count information is less than the threshold (e.g., the corresponding count buffers), as shown in operation 712, it is determined that the first read voltage V0 (or other read voltage during the iteration) is the optimal read voltage (e.g., the first optimal read voltage) of the current level of the current page.

When one of the optimal read voltages is determined for the current read level of the current page, as in operation 712, method 700 further proceeds to operation 714 in which whether all the optimal read voltages of all the read levels are done for the current page is determined. If not all the optimal read voltages of all the read levels of the current page are determined, method 700 further proceeds to operation 718, in which a next read voltage of the next read level for the current page is determined, and the next iteration can be repeated.

This iteration process flow is repeated until all the SLR levels on the current page have found their respective optimal read voltages.

Last, method 700 proceeds to operation 720, in which once all the SLR levels in the current page have found their respective optimal read voltages, the iteration reaches the end. And it is determined that all the optimal read voltages for the current page have been found.

FIG. 7B illustrates a flowchart of method 740 of determining an optimal read voltage, according to some implementations of the present disclosure. It can start with a coarse optimal read voltage determining operation, such as in operation 742. Based on the programmed data randomness characteristic, and by using the actual pattern of bit count information and the expected pattern of bit count information, as discussed above, a coarse optimal read voltage determining operation can find a coarse optimal read voltage. The coarse optimal read voltage can then be used as a default read voltage or a first read voltage to start a fine optimal read voltage process, as in operation 744.

The fine optimal read voltage determining operation can, for example, start with determining an initial SLR level for the current page.

Next, a third read operation is performed with a third read voltage of the first read level. In some implementations, as mentioned above, the initial single level read voltage includes a read retry voltage during the previous read retry operation, a default read voltage, or any optimal read voltage obtained in the present disclosure.

Next, a first shift-read operation is performed with the third read voltage plus a first offset voltage. In some implementations, the first offset voltage can be determined according to the threshold voltage normal distribution characteristic or the read margin of the memory device. For example, the first offset voltage can be between 0.01 and 1.0 V. It is noted that the lower the first offset voltage is (i.e., the smaller a shift step is), the more iterations the optimal read voltage determining operation may need.

Next, a second shift-read operation is performed with the third read voltage minus the first offset voltage.

Next, in response to that a difference between first bit flip information of the first shift-read operation and second bit flip information of the second shift-read operation is equal to or lower than a threshold, the third read voltage is determined to be the optimal read voltage for the current read level of the current page.

On the contrary, in response to that the difference between the first bit flip information of the first shift-read operation and the second bit flip information of the second shift-read operation is higher than the threshold, it is determined that the third read voltage is not the optimal read voltage for the current read level of the current page.

After determining that the third read voltage is not the optimal read voltage, a fourth read operation with a fourth read voltage is performed, where the fourth read voltage is determined based on a difference between the first bit flip information of the first shift-read operation and the second bit flip information of the second shift-read operation.

In particular, in response to that the first bit flip information of the first shift-read operation is higher than the second bit flip information of the second shift-read operation, the fourth read voltage is determined to be higher than the third read voltage, and in response to that the first bit flip information of the first shift-read operation is lower than the second bit flip information of the second shift-read operation, the fourth read voltage is determined to be lower than the third read voltage. In some implementations, in response to that the first bit flip information of the first shift-read operation is higher than the second bit flip information of the second shift-read operation, and the fourth read voltage is determined to be the third read voltage minus half of the first offset voltage, and in response to that the first bit flip information of the first shift-read operation is lower than the second bit flip information of the second shift-read operation, the fourth read voltage is determined to be the third read voltage plus half of the first offset voltage. By approaching the optimal read voltage with multiple iterations, the optimal read voltage for the current page can be found.

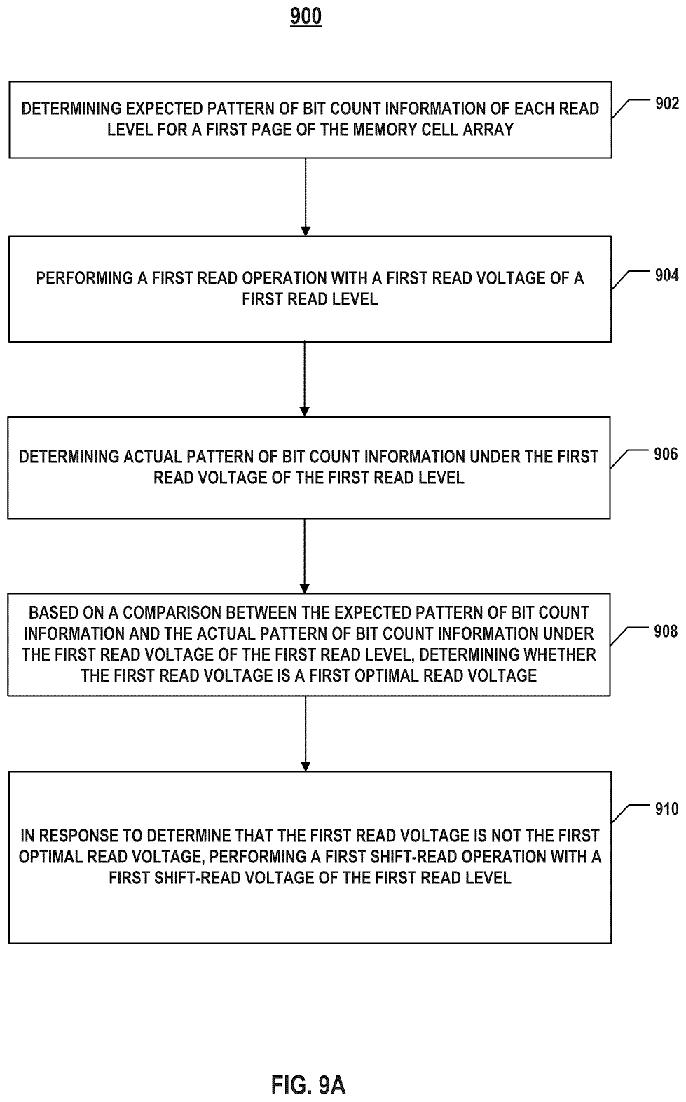

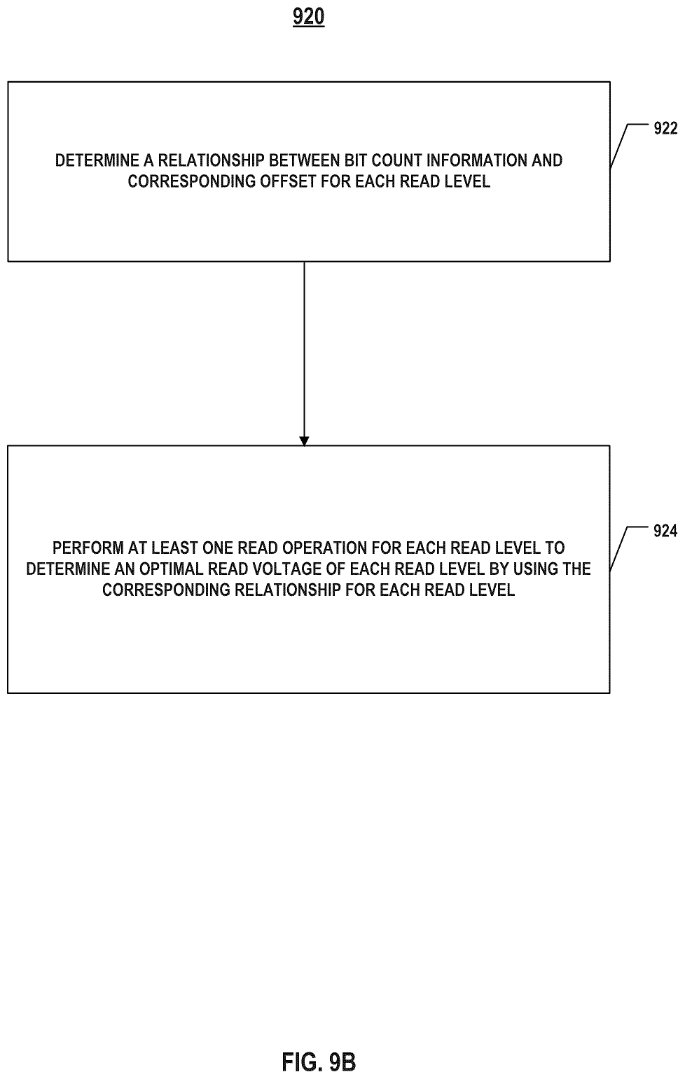

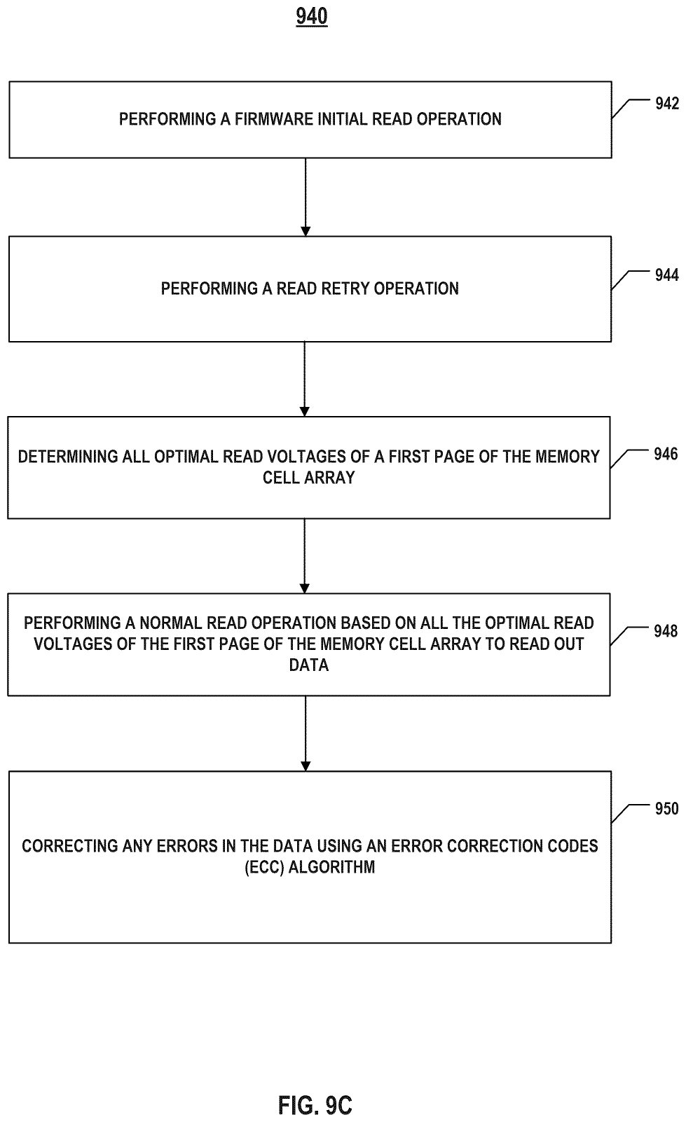

FIG. 9A illustrates a flowchart of method 900 for determining an optimal read voltage, according to some implementations of the present disclosure.

Method 900 starts at operation 902, in which the expected pattern of bit count information of each read level for a first page of the memory cell array is determined. For example, a program level P1 in a current page LP can be determined to be the first read level of the current page LP. All the above-mentioned expected patterns of bit count information, such as those in the implementations in FIGS. 6D and/or 6E, are determined.

Referring to operation 904 in which a first read operation is performed with a first read voltage of the first read level. In some implementations, as mentioned above, the initial single-level read voltage includes a read retry voltage during the previous read retry operation, a default read voltage, or any optimal read voltage obtained in the present disclosure.

Referring to operation 906 in which the actual pattern of bit count information under the first read voltage of the first read level is determined. For example, once the expected pattern of bit count information of program level P1 in the current page LP is determined, the above-mentioned actual pattern of bit count information, such as those in the implementations in FIGS. 6D and/or 6E, are calculated and determined.

Referring to operation 908 in which, based on a comparison between the expected pattern of bit count information and the actual pattern of bit count information under the first read voltage of the first read level, whether the first read voltage is a first optimal read voltage is determined.

Referring to operation 910 in which, in response to determining that the first read voltage is not the first optimal read voltage, performing a first shift-read operation with a first shift-read voltage of the first read level. By approaching the optimal read voltage with multiple iterations, the optimal read voltage for the current page can be found.

In some implementations, method 900 may further include, in response to determining that the first read voltage is the first optimal read voltage for a first page, determining a second single-level read level for the current page. Once all the optimal read voltages of all the respective read levels of the current page are determined, it may start to perform the same on the next page.

In some implementations, after all the optimal read voltages of all the respective read levels of the current page are determined, method 900 may further include performing a normal read operation based on all the optimal read voltages for the current page. It is noted that the normal read operation is not the single-level read operation.

FIG. 9B illustrates a flowchart of method 920 for determining an optimal read voltage, according to some implementations of the present disclosure.

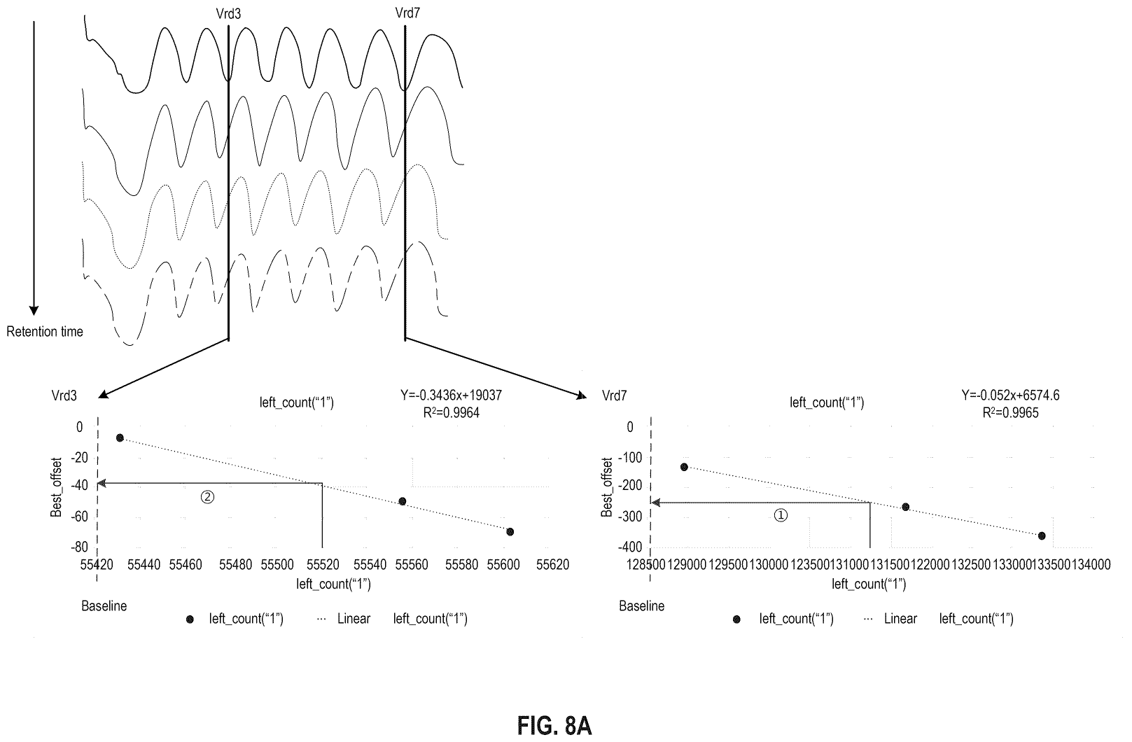

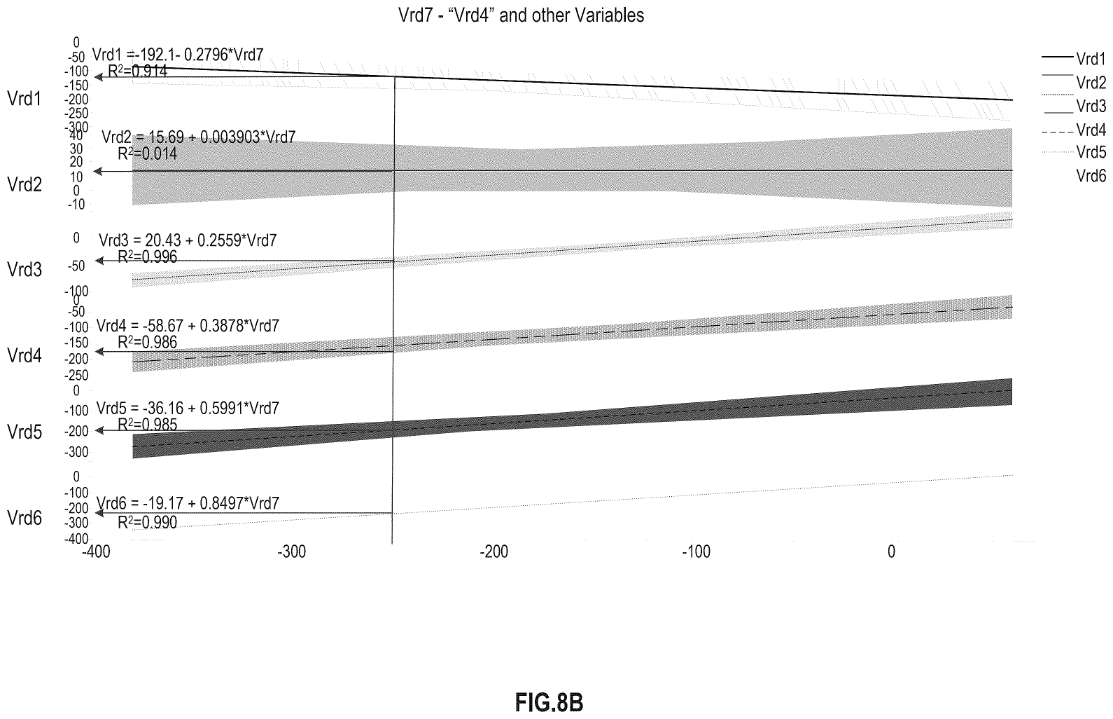

Method 920 starts at operation 922 in which a relationship between bit count information and corresponding offset for each read level of the current page is determined. As shown in FIG. 8A, a voltage distribution of read levels (e.g., read level P3 and read level P7) and corresponding relationships between read offset and bit count number in each read level are obtained and calculated or determined based on big data analysis of the memory device.

In some implementations, the big data analysis can be done by: (1) reading all the bit count information of all the corresponding Vth of NAND; (2) defining an estimated range for each read level; (3) calculating the delta value, which includes using a difference between two bit count information of two corresponding Vth; (4) calculating the relationship between the delta value and the offset of optimal read voltage for each read level; and (5) storing the relationship in the firmware. When checking with the relationship, at least one single-level read operation is performed to obtain a delta value. As such, by using the relationship and the delta value obtained, the optimal read voltage can be determined.

Referring to operation 924 in which at least one read operation for each read level of the current page is performed to determine an optimal read voltage of each read level by using the corresponding relationship for each read level. In some implementations, method 920 includes performing a first pre-read operation with a first pre-read voltage V0 to determine a first pre-read bit count information. Based on the first pre-read bit count information and a first relationship (e.g., a linear relationship) between bit count information and read offset in the first read level, a first read offset is determined. Then, by using the first read offset and the first pre-read voltage V0, the first optimal read voltage is determined. It is noted that the first read offset is an estimated offset (e.g., a left or right shift in read voltage) of voltage toward the optimal read voltage that is to be determined. The first optimal read voltage can be used as the first read voltage in other implementations of the above-mentioned optimal read voltage determining operation. This will significantly reduce the number of iterations in other optimal read voltage determining operations.

Once one of the read levels (e.g., the first read level of the first page) is determined, as shown in FIG. 8B, the relationship in the current read level of the current page can be further used to map to other read levels of the current page. For example, the relationships of other read levels of the first page can be determined by using the first relationship of the first read level of the first page.

FIG. 9C illustrates a flowchart of method 940 for read recovery, according to some implementations of the present disclosure. Method 940 starts at operation 942 in which a firmware initial read operation is performed. If the firmware initial read operation fails, method 940 proceeds to operation 944 in which a read retry operation is performed. Next, if the read retry operation fails, method 940 proceeds to operation 946 in which all optimal read voltages of a first page of the memory cell array are determined. It is noted that, as mentioned above, the optimal read voltage determining operation can be performed before, within, or after the read retry operation. The optimal read voltage found in the read retry operation can be used as an initial read voltage in the optimal read voltage determining operation, and vice versa. Accordingly, the optimal read voltage can be determined as precisely as possible without reducing the overall performance of the memory device. Next, method 940 proceeds to operation 948 in which a normal read operation is performed based on all the optimal read voltages of the first page of the memory cell array to read out data. Next, method 940 proceeds to operation 950 in which error correction codes (ECC) are used to detect and correct any errors in the data. It is noted that the ECC can also be performed before, within, or after the read retry operation.

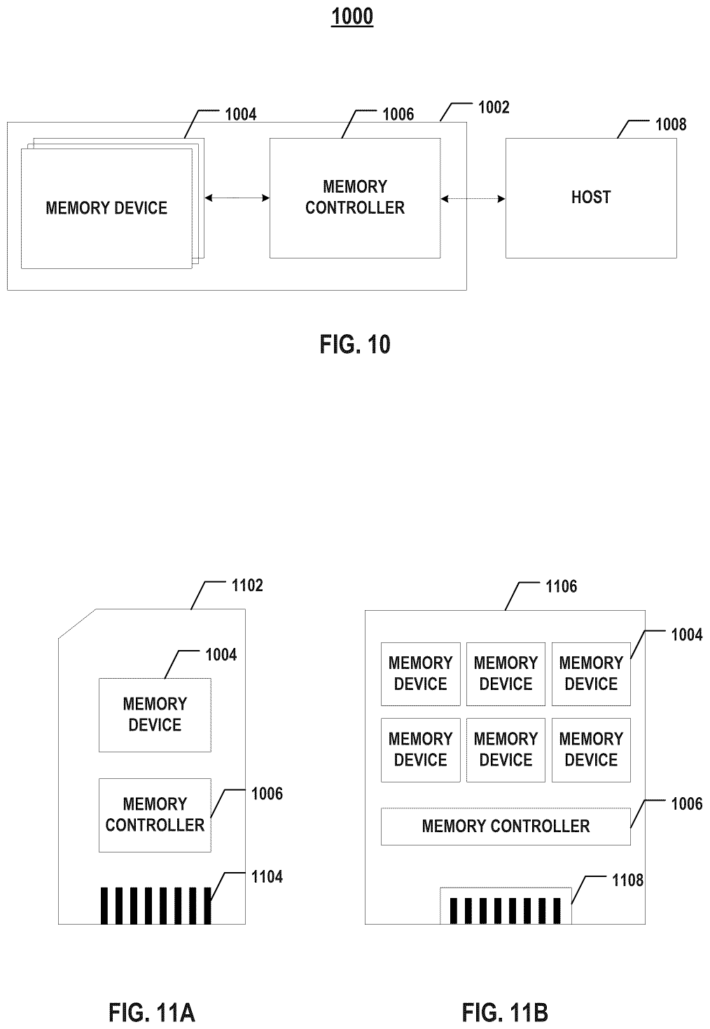

FIG. 10 illustrates a block diagram of a system 1000 having a memory device, according to some aspects of the present disclosure. System 1000 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 10, system 1000 can include a host 1008 and a memory system 1002 having one or more memory devices 1004 and a memory controller 1006. Host 1008 can be a processor of an electronic device, such as a central processing unit (CPU), or a system-on-chip (SoC), such as an application processor (AP). Host 1008 can be configured to send or receive the data to or from memory device 1004.

Memory devices 1004 can be any memory devices disclosed herein, such as memory devices 100. In some implementations, each memory device 1004 includes a memory device, as described above in detail.

Memory controller 1006 is coupled to memory device 1004 and host 1008 and is configured to control memory device 1004, according to some implementations. Memory controller 1006 can be any memory controller disclosed herein, such as memory controller 300. In some implementations, each memory controller 1006 includes a memory controller, as described above in detail. Memory controller 1006 can manage the data stored in memory device 1004 and communicate with host 1008. In some implementations, memory controller 1006 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1006 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1006 can be configured to control operations of memory device 1004, such as read, erase, and program operations. Memory controller 1006 can also be configured to manage various functions with respect to the data stored or to be stored in memory device 1004 including, but not limited to bad-block management, garbage collection, logical-to-physical address conversion, wear leveling, etc. In some implementations, memory controller 1006 is further configured to process error correction codes (ECCs) with respect to the data read from or written to memory device 1004. Any other suitable functions may be performed by memory controller 1006 as well, for example, formatting memory device 1004. Memory controller 1006 can communicate with an external device (e.g., host 1008) according to a particular communication protocol. For example, memory controller 1006 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1006 and one or more memory devices 1004 can be integrated into various types of storage devices, for example, be included in the same package, such as a universal Flash storage (UFS) package or an eMMC package. That is, memory system 1002 can be implemented and packaged into different types of end electronic products. In one example as shown in FIG. 11A, memory controller 1006 and a single memory device 1004 may be integrated into a memory card 1102. Memory card 1102 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1102 can further include a memory card connector 1104 coupling memory card 1102 with a host (e.g., host 1008 in FIG. 10). In another example as shown in FIG. 11B, memory controller 1006 and multiple memory devices 1004 may be integrated into an SSD 1106. SSD 1106 can further include an SSD connector 1108 coupling SSD 1106 with a host (e.g., host 1008 in FIG. 10). In some implementations, the storage capacity and/or the operation speed of SSD 1106 is greater than those of memory card 1102.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A method of operating a memory system, comprising:
performing a first read operation with a first read voltage of a first single read level;
determining an actual pattern of bit count under the first read voltage of the first single read level; and
in response to that a difference between an expected pattern of bit count and the actual pattern of bit count under the first read voltage of the first single read level is equal to or lower than a first threshold, determining that the first read voltage is a first optimal read voltage, wherein the first single read level of a first page is under a multi-level architecture.

2. The method of claim 1, wherein in response to that the difference between the expected pattern of bit count and the actual pattern of bit count under the first read voltage of the first single read level is higher than the first threshold, determining that the first read voltage is not the first optimal read voltage.

3. The method of claim 1, wherein the expected pattern comprises an expected ratio of bit count, and the actual pattern comprises an actual ratio of bit count.

4. The method of claim 2, wherein in response to determining that the first read voltage is not the first optimal read voltage, the method further comprises:
performing a first shift-read operation with a first shift-read voltage of the first single read level, wherein the first shift-read voltage is determined based on a comparison between the expected ratio of bit count and the actual ratio of bit count under the first read voltage of the first single read level.

5. The method of claim 4, wherein the first shift-read voltage is determined based on a comparison between an expected ratio of bit count and an actual ratio of bit count under the first read voltage of the first single read level further comprises:
in response to that the expected ratio of bit count is higher than the actual ratio of bit count, the first shift-read voltage is determined to be higher than the first read voltage; and
in response to that the expected ratio of bit count is lower than the actual ratio of bit count, the first shift-read voltage is determined to be lower than the first read voltage.

6. The method of claim 5, wherein:
in response to that the expected ratio of bit count is higher than the actual ratio of bit count, the first shift-read voltage is determined to be the first read voltage plus a first offset voltage; and
in response to that the expected ratio of bit count is lower than the actual ratio of bit count, the first shift-read voltage is determined to be the first read voltage minus a first offset voltage.

7. The method of claim 3, wherein after performing the first read operation with the first read voltage of the first single read level, the method further comprises:
counting bit count under the first read voltage of the first single read level.

8. The method of claim 7, wherein counting bit count under the first read voltage of the first single read level further comprises:
counting bit count of target memory cells, all the memory cells in a target page, memory cells in one or more pages including the target page, or all the memory cells in all the pages.

9. The method of claim 3, wherein determining actual pattern of bit count under the first read voltage of the first single read level further comprises:
calculating a ratio of a first actual bit count to a second actual bit count to determine the actual ratio of bit count, and wherein determining expected ratio of bit count of each read levels for the first page comprises:
calculating a ratio of a first expected bit count to a second expected bit count to determine the expected ratio of bit count.

10. The method of claim 1, wherein in response to determining that the first read voltage is the first optimal read voltage, the method further comprises:
determining a second voltage of a second single read level.

11. The method of claim 10, wherein in response to determining all the optimal read voltages, the method further comprises:
performing a normal-read operation based on all the optimal read voltages, wherein the normal-read operation is not a first read operation.

12. The method of claim 1, further comprising:
performing a first pre-read operation with a first pre-read voltage;
based on a first bit count in the first pre-read operation and a first relationship between bit count and read offset in the first single read level, determining a first read offset; and
determining the first read voltage based on the first pre-read voltage and the first read offset.

13. The method of claim 12, further comprising:
determining each relationship for each read level using the first relationship of the first single read level.

14. The method of claim 13, wherein determining each relationship for each read level further comprises:
determining each relationship between a first voltage offset of the first single read level and each of other voltage offsets of other read levels.

15. The method of claim 14, wherein after determining that the first read voltage is a first optimal read voltage, and in response to that a number of an error correction code (ECC) error is greater than an ECC threshold, the method further comprises:
performing a second read operation with the first optimal read voltage of the first single read level;
performing a first shift-read operation with the first optimal read voltage plus a first offset voltage;
performing a second shift-read operation with the first optimal read voltage minus the first offset voltage; and
in response to that a difference between first bit flip information of the first shift-read operation and second bit flip information of the second shift-read operation is equal to or lower than a second threshold, determining that the first optimal read voltage is a second optimal read voltage.

16. The method of claim 15, further comprising:
in response to that the difference between the first bit flip information of the first shift-read operation and the second bit flip information of the second shift-read operation is higher than the second threshold, determining that the first optimal read voltage is not the second optimal read voltage; and
performing a third read operation with a third read voltage, wherein the third read voltage is determined based on the difference between the first bit flip information of the first shift-read operation and the second bit flip information of the second shift-read operation.

17. The method of claim 1, further comprising:
determining all optimal read voltages; and
performing a normal-read operation based on all the optimal read voltages to read out data.

18. A memory device, comprising:
a memory cell array comprising memory cells; and
a peripheral circuit coupled to the memory cell array, wherein the peripheral circuit is configured to:
apply a first read voltage of a first single read level to target memory cells in a first read operation; and
apply a first shift-read voltage of the first single read level to the target memory cells in a first shift-read operation, wherein the first shift-read voltage is determined based on bit count under the first read voltage of the first single read level.

19. The memory device of claim 18, wherein the peripheral circuit is further configured to:
store the bit count in a page buffer of the peripheral circuit or the memory cell array.

20. A memory system, comprising:
a memory device; and
a memory controller coupled to the memory device, wherein the memory device comprises:
a memory cell array comprising memory cells; and
a peripheral circuit coupled to the memory cell array,
wherein the memory controller is configured to:
perform a first read operation with a first read voltage of a first single read level;
determine an actual pattern of bit count under the first read voltage of the first single read level; and
in response to that a difference between an expected pattern of bit count and the actual pattern of bit count under the first read voltage of the first single read level is equal to or lower than a first threshold, determine that the first read voltage is a first optimal read voltage, wherein the first single read level of a first page is under a multi-level architecture.
